(19) United States
(12) Patent Application Publication
(10) Pub. No.: US 2014/0005965 A1
(43) Pub. Date: Jan. 2, 2014

(54) Method of Evaluating Remaining Power of a Battery for Portable

(71) Applicants: Mikael Martti Vaino Vestama, Helsinki (FI); Jussi Pekka Olavi Ruutu, Espoo (FI)

(72) Inventors: Mikael Martti Vaino Vestama, Helsinki (FI); Jussi Pekka Olavi Ruutu, Espoo (FI)

(73) Assignee: Nokia Corporation, Espoo (FI)

(21) Appl. No.: 13/699,115

(22) PCT Filed: May 27, 2010
(86) PCT No.: PCT/IB2010/001262

§ 371 Date: Mar. 25, 2013

(51) Int. Cl. G01R 31/36

(52) U.S. Cl. CPC G01R 31/3624
USPC 702/63

(57) ABSTRACT

A remaining energy E of a battery is estimated based on a measurement of a momentary voltage and a momentary current. E is defined as a function of its voltage U or power owing to a characteristic function (E/U) or (E/P). Instead of the function, a lookup table can be used. E/U function is defined by using a reference battery having the same or similar characteristics. A set of low and high current or power loads are applied to the reference battery to cause voltage drops which are measured and then used to determine function (E/U) and a parameter Alpha which is specific to the type of reference battery. During the operation of the battery, momentary voltage and current are measured and Alpha is used to correct the momentary voltage. Afterwards, function (E/U) enables to estimate E. The battery size is used to scale E for a better estimation.

### TECHNICAL FIELD

The present application relates generally to a battery energy or power management of portable devices and more particularly to a method and apparatus for estimating remaining energy or power of a battery based on momentary voltage and momentary current without continuous monitoring or real-time measurements of the battery voltage and current.

### BACKGROUND

There are different types of portable devices that are powered by batteries. Mobile phones are an example of portable devices. The battery life or the remaining energy or power of a battery is of considerable importance to their users. Consequently, the provision of battery remaining energy on mobile phones is an utmost requirement for their users.

Some cell phones that are available on the market, are provided with an Energy Management Server and chipset which are used to estimate the remaining energy of the battery. They are used to monitor the voltage of the battery in close-to-open circuit when no current is being drawn. Once the cell phone starts operating, more current is drawn and the Energy Management Server will integrate the energy consumed or drawn from the battery which is energy=power×time. The energy estimation is then updated based on the last known close-to-open circuit voltage minus the integrated energy consumption. This method of estimating the remaining energy requires hardware support which uses real-time integration of the current drawn from the battery and which imposes a constant monitoring of the battery current, based on the formula of (Eq. 1) that will be defined later in the detailed description.

### SUMMARY OF THE INVENTION

According to a first aspect of the invention, an estimation of a remaining energy or remaining power of a battery operated device is based on the measurement of a momentary voltage and a momentary current without any long-term integration and monitoring of the battery current and voltage.

According to a second aspect of the invention, the method of estimating the remaining energy or power of a battery operated device may be implemented in an Application Engine of a cell phone or a portable device rather than in an Energy Management chipset. Accordingly, the estimation of the remaining energy or power of a battery which does not assume a constant monitoring of the battery is more energy efficient.

The present invention may be used with a battery wherein its energy E is defined with a mathematical function of its voltage U or wherein a characteristic mathematical function (ETU) may be defined in general. Alternatively, a lookup table may also be used instead of the characteristic mathematical function (E/U).

The momentary voltage of the battery as well as the momentary current or power may be measured either during the operation of the battery operated device at one point in time, or during predetermined time or events. The measured momentary voltage is then corrected or adjusted in view of the characteristics mathematical function of a reference battery previously tested with various series of voltage drops. During that test, a series of current or power loads are applied to the reference battery to determine the series of voltage drops as a function of the series of current or power loads being drawn from the reference battery and to determine a parameter Alpha which is specific to the type of identical or similar to the reference battery being used.

Having determined the corrected voltage U=Vbat+P/Alpha, the characteristic mathematical function (E/U) is then used in order to evaluate the remaining energy E of the battery.

In order to have a more accurate remaining energy, E is scaled according to a nominal battery capacity size B_size to determine an estimate value E_est=function (E, B_size). If the estimate value E_est is not stable, it may be averaged using an exponentially moving average function such that E_ave=function (Est_est). Any other method may be used for averaging the estimate value E_est to prevent important fluctuations. But if the estimate value E_est is stable enough, E_ave may be set equal to E_est.

According to the present invention, an example of battery is a Lithium Ion battery type that may be used in mobile handheld devices, but any other type of battery where the energy may be determined as a function of the voltage may be used.

### BRIEF DESCRIPTION OF THE DRAWINGS

A more complete understanding of the example embodiments of the invention is made with reference to the following figures.

FIG. 1 shows a block diagram of a battery operated device according to the present invention.

FIG. 2A shows a more detailed block diagram of a battery operated device according to the present invention.

FIG. 2B shows an implementation of a method using an Energy Management circuitry described in FIG. 2A to obtain the momentary voltage of the battery according the present invention.

FIG. 2C shows an implementation of a method of obtaining the momentary current of the battery according to the present invention.

FIG. 3 shows a method of estimating a remaining energy in the battery according to the present invention.

FIG. 4A shows a graph of the remaining energy versus battery voltage U for a constant and low power consumption and consequently insignificant voltage drop.

FIG. 4B shows a graph of the remaining energy versus battery voltage U for higher voltage drops caused by significant power consumption levels of the battery.

FIG. 5A shows a graph of the remaining energy as a function of corrected battery voltage defined by a mathematical function f1.

FIG. 5B shows an example flowchart of the algorithm of the mathematical function f1.

### DETAILED DESCRIPTION OF THE INVENTION

Each battery is classified according to its parameters or behavior, i.e. its battery characteristics. If the characteristics of a new battery are unknown, before the estimation according to the present invention is used, its parameters or behavior are to be defined or calibrated.

To define the battery characteristics, its energy versus voltage characteristics (E/U) or the variation of the energy as a function of the voltage is to be determined. The energy vs. voltage data measurements may be carried out both in idle state and in discharge state where various loads are applied to the battery.

In idle state, the battery is implemented in a close-to-open circuit and small amounts of power are extracted from the battery and the values of the electrical current I and voltage U are measured successively at several points in time until complete depletion of the battery energy in order to draw an (E/U) graph.

The (E/U) graph is then used to determine a mathematical function that may fit the curve as closely as possible. Instead of determining the mathematical function, a lookup table containing the values of energy E and voltage U may also be used.

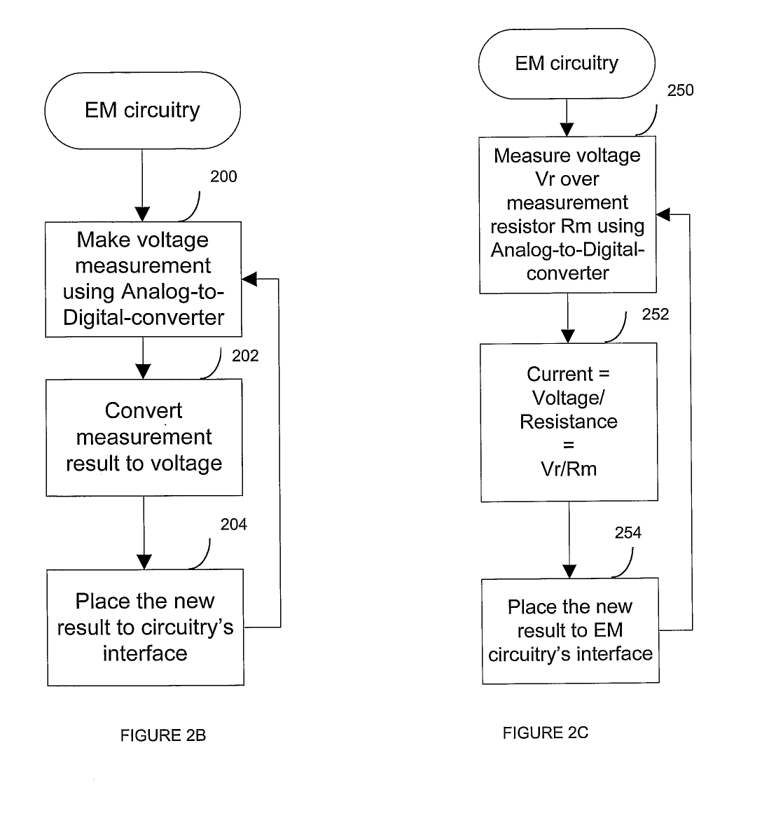

It should be understood that the battery voltage does not only depend on the energy remaining in the battery but also on the electrical load or current that is drawn from the battery. More specifically, the current drawn from the battery tends to decrease the observable battery voltage due to an internal resistance of the battery. The internal resistance is referred as Rint in FIG. 2A. While Rint is not a real resistor component, it is a useful concept for modeling the characteristics of a non-ideal battery.

For modeling the characteristics of the non-ideal battery, a series of test loads are applied to the battery in order to determine the variation of the voltage drop ΔU as a function of the current I drawn from the battery. An (ΔU/I) graph is then plotted by measuring successively at several points the values of the voltage drop ΔU and the current I drawn from the battery.

It is also possible to determine the variation of the voltage drop as a function of the power (P=UI) of the battery and to plot an (ΔU/P) graph by measuring the power P being drawn from the battery.

These test loads of a battery may be carried out in two different ways:
As part of the battery predefined parameters or specificities. In such case, a fixed mathematical function is assigned for each type of battery and such mathematical function is then used to determine the values of both (ΔU/I) or (ΔU/P) in the method of present invention, or
During the operation of the cell phone or the battery operated device. In such case, the test load may be carried out by a separate calibration resistor or by a component such as a display backlight whose current or power is known. This will then allow a dynamic adjustment which may factor in the aging of the battery, the temperature changes etc. This dynamic adjustment will allow better accuracy of the values of ΔU and I or P, and it does not need to be carried out all the time or in real-time during the lifetime of the battery.

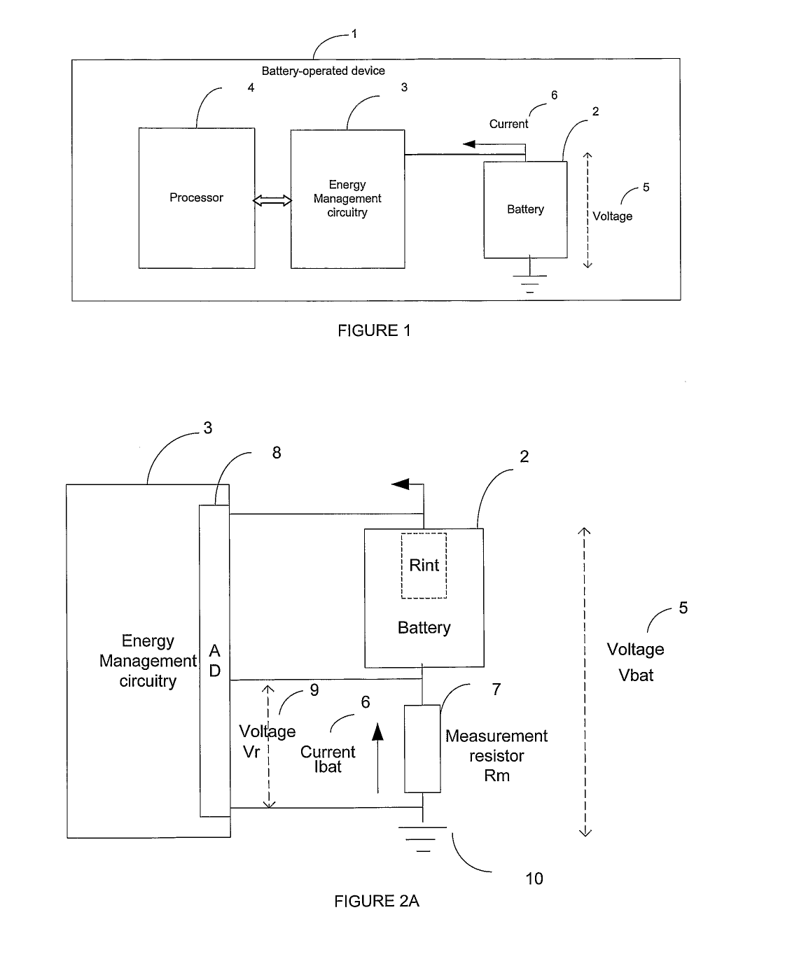

FIG. 1 illustrates a block diagram of a battery operated device 1 which may be any portable electronic device such as a cell phone, a laptop or a notebook etc. The battery operated device 1 may comprise one or more battery 2, an electrical circuit 3 referred as Energy Management (EM) circuitry and a processor 4. Energy management circuitry 3 is able to measure electrical voltage 5 and electrical current 6 and to calculate parameters which are specific to the type of battery 2. These specific parameters will described in more detail later in the description. The energy management circuitry 3 may include a memory (not shown in FIG. 1) for storing the measured electrical voltage and electrical current. The memory may also contain registers for storing the parameters specific to the type of battery 2.

The energy management circuitry 3 may further include a measuring device for measuring battery 2 momentary voltage referred as Vbat and momentary current referred as that. The power consumption P is then determined by P=Vbat*Ibat; and depending on the implementation of the Energy Management circuitry 3, it may retrieve any two of these values or all three of them to an application engine with a user interface.

In another implementation, the energy management circuitry 3 may be connected to a plurality of batteries 2 of a single type or of different types. In case there are different types of batteries 2, the memory may also contain a plurality of registers for storing the parameters specific to the different types of batteries 2. Conversely, the measuring device will perform the measuring of the momentary voltage and current of these different types of batteries 2.

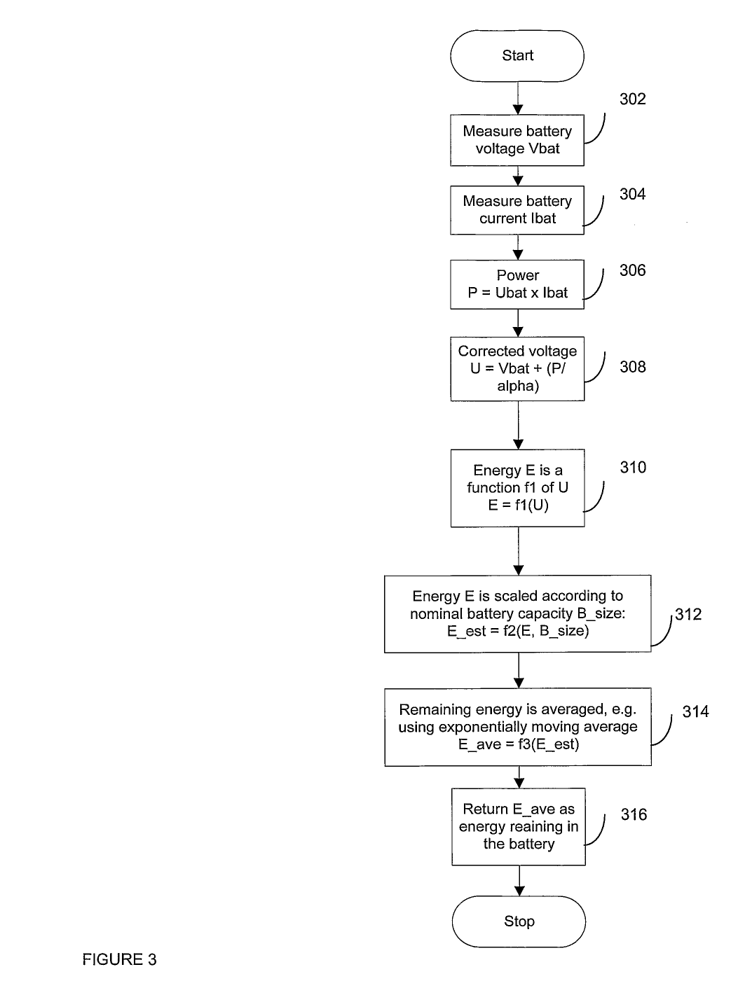

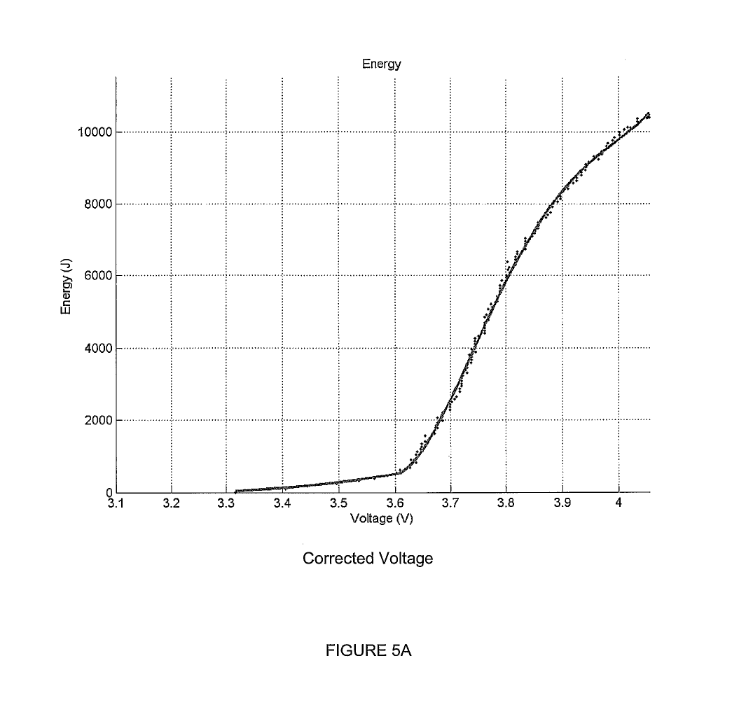

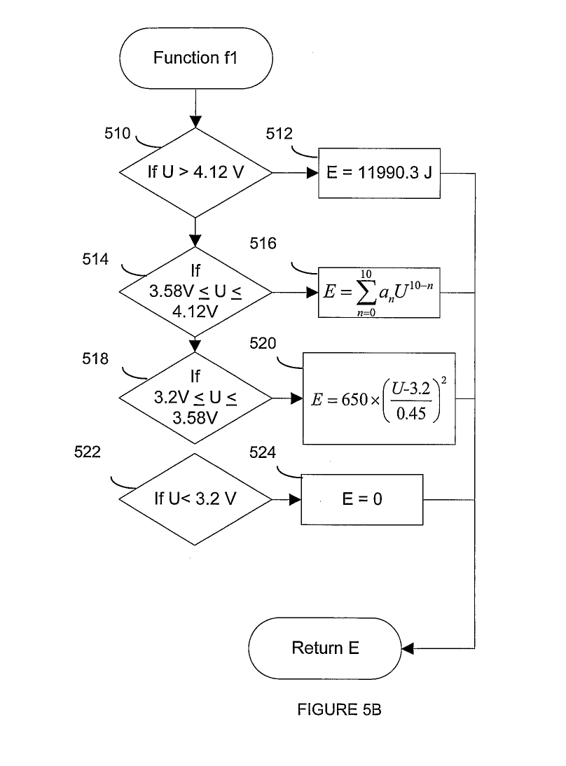

Processor 4, which may be any suitable processing device in a battery operated device 1, may be programmed to perform the mathematical functions such as the multiplication and division of the different measurements of the voltage Vbat and current that or power P, and the comparison with various constants to generate different values that may be retrieved to the Energy Management circuitry 3. Alternatively, these mathematical functions may also be implemented in the EM circuitry 3 and they will be described in more details in FIGS. 3 and 5B.

For example, processor 4 may be part of a cellular modem referred as (CMT) which contains a number of servers which are dedicated to specific functions. These servers handle many real-time related issues at the low level communication protocols.

Processor 4 may also be a part of an application engine referred as (APE) that is used to handle a user interface and many other application level tasks. In this configuration, a dual-chip architecture may be implemented. The second chip is then dedicated to the application engine (APE) which is also used to run the Operating System such as Symbian or MAEMO/linux. Other applications such as the web browser, MP players etc. may also run in the APE.

As mentioned above, processor 4 may handle various mathematical functions. One of which is the estimation of remaining energy of battery 2. In a single chip architecture, these measurements and functions are managed within the CMT. In a dual chip architecture, some of the measurements and parameters are transmitted to the APE. These measurements and parameters may be for instance the battery momentary voltage Vbat, the battery momentary current Ibat or the momentary power consumption P, or the battery nominal capacity which represents the maximum amount of energy that may be stored in the battery.

FIG. 2A illustrates more details of the block diagram of a battery operated device of FIG. 1. Several methods exist in literature for obtaining the battery momentary voltage 5 Vbat and battery momentary current 6 that. The following description is one example presented without departing from the spirit and the scope of the present invention. It should be understood that various methods are available for the measurements of the battery Vbat and Ibat. FIG. 2A illustrates just one example of circuitry used for measuring battery voltage Vbat 5 and current that 6.

A measurement resistor referred as Rm 7 is provided with an electrical resistance and is connected between battery 2 and an electrical ground 10 of the battery operated device 1. Alternatively, it is also possible to connect resistor Rm 7 to the positive end of battery 2.

Although the values of resistor Rm 7 between battery 2 and ground 10 are detectable, they are very small. EM circuitry 3 measures the current flowing out of the battery 2 which causes a voltage drop, referred as Vr, over the measurement resistor Rm 7. As a matter of fact, each time a battery current that 6 flows through Rm 7, it causes the voltage drop Vr 9.

The voltage drops may be measured using various circuitry and methods, such as for example an Analog-to-Digital Converter 8 as show in this FIG. 2A. A detailed description of AD converter 8 is omitted since any standard AD converter known in the industry for the measurement of the voltage drops may be used. The AD converter 8 is also capable of measuring the battery voltage Vbat 5 that is the electrical voltage between the positive terminal of the battery and the electrical ground 10 of the battery operated device 1. The AD converter 8 is connected to EM circuitry 3 as shown in FIG. 2A, but it may also be integrated to the EM circuitry 3 in another implementation.

It should also be kept in mind that a processor, a memory and/or a measuring device may be implemented in a single chip architecture as shown in FIG. 2A. In case a plurality of batteries 2 are used, they may be connected either in parallel or in series. Thus, each of these batteries may have its own parameters Vbat and that and power consumption P.

In a dual chip architecture, the second chip which has a dedicated application engine (APE) is connected to the first chip to receive the measurements and parameters from the first chip and to process them and store the results in its own memory.

As mentioned before, for the purpose of modeling of a non-ideal battery, battery 2 has an internal resistance Rint. While it is not a real resistor component, it may be considered as a virtual resistor inside battery 2 which creates the battery voltage drops when the electrical current is drawn.

FIG. 2B illustrates an example of implementation of a method using EM circuitry 3 described in FIG. 2A to make the measurements of the battery voltage. In this implementation, EM circuitry 3 measures the momentary voltage of battery 2 using AD converter 8 in step 200. In step 202, AD converter 8 converts the measurement to a meaningful battery voltage Vbat 5. In step 204, the value is stored in a register for any other computational operations when required. The different values of battery voltage Vbat 5 may also be retrieved to an EM circuitry interface for other further use.

FIG. 2C illustrates an exemplary implementation of a method of obtaining battery current Ibat 6. EM circuitry 3 measures voltage drop Vr 9 across the measurement resistor Rm 7 using AD converter 8. In step 250, using the well-known Ohm's Law, battery current that 6 is obtained by dividing voltage drop Vr 9 by the electrical resistance of resistor Rm 7 in step 252. The value of battery current that 6 is then stored in a register for any other computational operations. When required, the different values of Ibat may also be retrieved to the EM circuitry interface for further use in step 254.

FIG. 3 illustrates an example of method of estimating the remaining energy in the battery according to the present invention. Once battery voltage Vbat and current that are respectively measured in steps 302 and 304 as shown in FIG. 2B and FIG. 2C, a power P is calculated by multiplying Vbat to that in step 306. Alternatively, instead of measuring the that, it is possible to measure the power after step 302 and to jump directly to step 306.

Since the internal resistance Rint of the battery creates an additional voltage drop, the measured voltage Vbat is to be corrected in order to use the known relationship of energy E vs voltage U by removing this additional voltage drop. This type of correction depends on the battery chemistry. An example of measurement and correction are herein given with the observed characteristics of a Li-Ion battery.

Thus, in step 308, a corrected voltage U (also referred as idle voltage) is computed by using the equation:

U=Vbat+(Power/Alpha)

The corrected voltage U is the estimation of the idle battery voltage, which corresponds to the voltage Vbat if no current was drawn from battery 2; and there is no associated battery voltage drop caused by battery's internal resistance in such case.

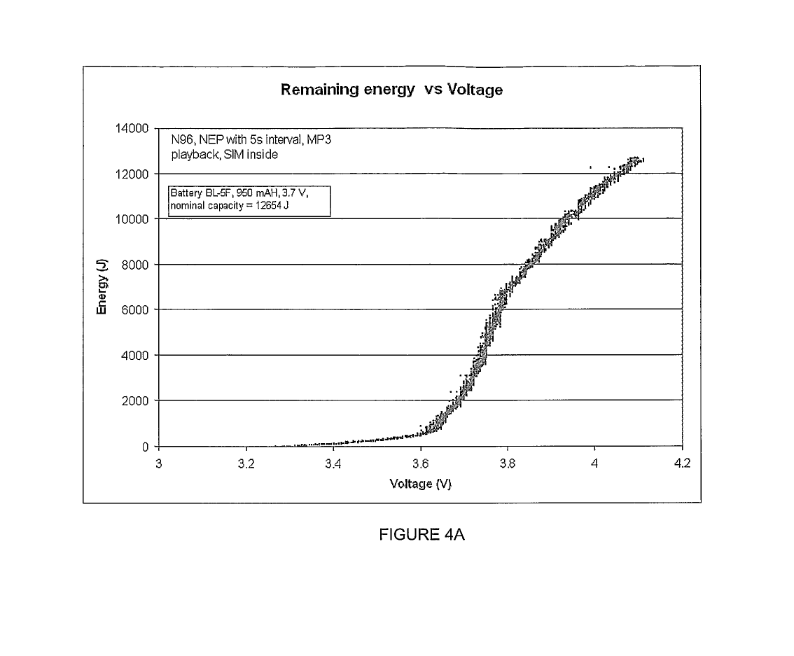

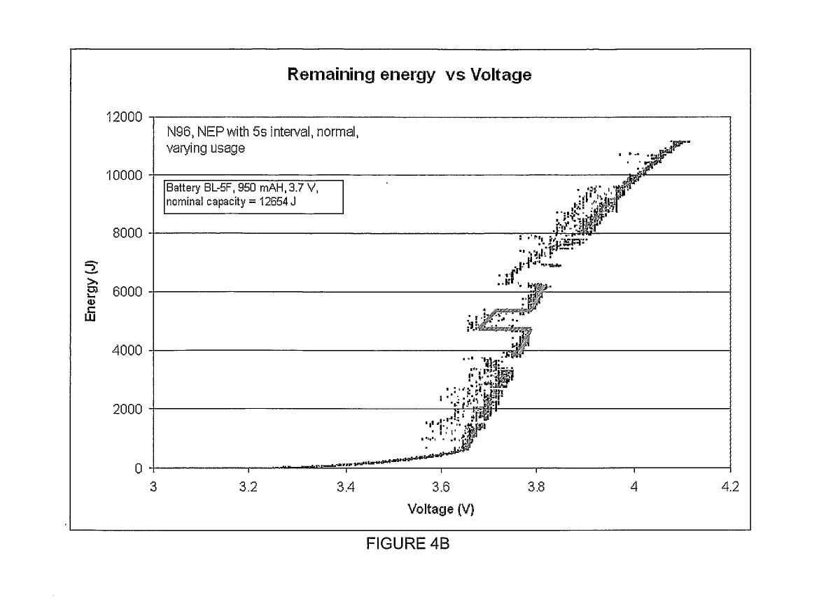

Alpha is a parameter (watts per volt) and represents an ‘image’ of the battery's internal resistance Rint. Parameter Alpha may be obtained by experimentation by observing voltage Vbat with various levels of battery power which is the product of voltage with current. As a matter of fact, according to the measurements shown in FIG. 4B, the voltage drop of the battery may be basically a linear function of drawn power, at least in the Lithium-ion type of batteries. It is also possible that other, more complex functions may be used, such as a polynomial function to characterize the voltage drop due to the internal resistance. Therefore, the voltage that is used in the calculation of remaining battery energy E is to be corrected by this voltage drop. The voltage drop in this example is approximately (P/Alpha) and Alpha may be in the range of values between 5 and 50, and it may also be outside that range of values.

Parameter Alpha is obtained for instance by comparing the power loads P to the voltage drops ΔU at different power load levels. This comparison may be a correlation between the power loads P and the resulting voltage drops ΔU. Furthermore, depending on the type of battery, parameter Alpha may be assimilated to either a constant or polynomial function. If parameter Alpha is always constant with low and high power loads P, then the relationship between the power loads P applied to the battery and the measured voltage drops ΔU is linear and Alpha=ΔU/P.

If parameter Alpha varies for different power loads, then the relationship between the power loads P applied to the battery and the measured voltage drops ΔU is not linear and a polynomial function is used to correct the voltage drop caused by the power loads P.

In step 310, a value of remaining energy E is computed using a function f1 that converts the corrected (or idle) voltage U previously obtained into battery energy estimate E_est. Function f1 is determined through measurements by observing battery voltage Vbat and its relationship with battery energy level E as follows.

To determine function f1, the battery is fully recharged and then it is discharged until it becomes empty. While the battery is discharging, the battery voltage Vbat and current Ibat are measured. Power P may be obtained by multiplying the current That and voltage Vbat at any given point of time. If this discharge is made with very low current (or power), then battery's internal resistance may be omitted and the measured Vbat is used directly as the corrected voltage U for function f1. If the discharge is made using higher currents, then the corrected voltage U=Vbat+(P/alpha) is to be used.

The battery becomes empty once its voltage level is too low that any operation of the circuitry of the battery operated device cannot be performed. This cut-off limit may vary from one device to another. Energy E may be obtained by integrating the power over time. This means that it is possible to reconstruct the energy taken out of from the battery by making such integration. Mathematically, this may be expressed, for example, as:

E(t1)=∫ₜ₌₀^{t=t1}U(t)I(t)dt (Eq. 1)

where E(t1) is the energy taken out of the battery by time t1.

Since typically the voltage and current are measured in a discreet way, at separate time intervals, the energy taken from the battery by time t1 may be calculated as:

E(t1)=Σₜ₌₀^{t=31}U(t)I(t)Δt(t) (Eq. 2)

where U(t) is the measured voltage at time t,
I(t) is the current measured at time t and
Δt(t)is the interval between the measurements.

The total energy taken from the battery is then E_tot=E(t=t_final) where t_final is the time when the battery becomes empty (cut-off limit and the low level of the battery voltage is reached).

Afterwards, it is possible to calculate the energy in the battery at time t by subtracting from the total energy E_tot the energy taken from the battery by time t. Since voltage U is known at time t, it is possible to reconstruct the relationship between energy E in the battery and voltage U of the battery.

FIG. 5A shows an example of such a reconstruction in a series of dots. Each dot shows the remaining energy E as a function of voltage U. This dependence of remaining energy on voltage may be saved as a look-up table in the memory. Another alternative method is to fit a mathematical function to the results using any suitable method known in the literature. Mathematically, this relationship may be expressed as a function f1:

E=f1(U)

Such fit mathematical function f1 is shown with solid line as an example of a fitted function in FIG. 5A.

FIG. 5B expresses the algorithm of function f1 with its coefficients and how such an example function may be implemented in the circuitry. It should be noted that there exist various functions with different coefficients that may be used.

Thus, function f1 may be a mathematical equation with coefficients computed by EM circuitry 3, the details of which are given in the description of the graph shown in FIG. 5A and of the flowchart shown in FIG. 5B. The distinction between graphs of FIGS. 4A and 5A is that the graph of FIG. 4A is obtained with the measurements whereas the graph of FIG. 5A is obtained with the function f1. FIG. 4B is used as an intermediary step to obtain the value of Alpha.

It should also be kept in mind that instead of using the mathematical function f1, a look-up table with predefined values may be used by EM circuitry 3 to determine the value of energy E in step 310 as a function of the corrected voltage U calculated in step 308.

Since such experimental estimation of function f1 is based on measurements with a battery of a certain size or capacity, in step 312 another function f2 is used to scale the energy based on the battery size referred as B_size. For example, if the battery measurements are made with a battery having a size or capacity of 968 mAh, then function f2 enables to scale energy E with a scaling factor by multiplying energy E with the scaling factor (B_size/968) which gives a more accurate energy estimation E_est since the battery size used for the calculation of the battery characteristics for which the original measurements were made, was an 968 mAh battery.

Thus in the present case, function f2 may be defined as:

E_est=f2(E,B_size)=E×(B_size/968).

This scaling factor is used if the battery with B_size has similar battery characteristics to the battery for which the original measurements were made. In this example, the measurements were made by an N96 Nokia mobile, which had a BL-5F battery of size 968 mAh. For some batteries other than the BL-5F battery used in the N96 mobile which have the same battery characteristics as the BL-5F battery, the scaling method may apply. One example of such battery is the 1500 mAh sized BP-4L battery that is used for instance in the E71 or E72 Nokia Model. E_est may be directly used for the estimation of the energy but a better result is obtained by averaging consecutive samples of E_est. As a matter of fact, because of the deviations of the battery voltage level and those of the measurements samples, the energy estimation is averaged for example over 3 minutes to smooth the deviations. Averaging consecutive samples of E_est may be obtained by using various known methods in literature. For example, in step 314, a function f3 for averaging samples may be a so called exponentially moving average. Therefore, according to the present invention, the average energy E_ave is used as the best estimation of the remaining energy of the battery. E_ave is accordingly computed by EM circuitry 3 as an estimate of the remaining energy in battery 2 based on the measurements of momentary voltage and current Vbat and Ibat of battery 2.

For example function f3 is defined as: E_ave=f3 (E_est) wherein:

$$f 3 = ( 1 - \frac{Δ T}{τ} ) \times E\_ave + ( \frac{Δ T}{τ} ) \times E\_est$$

ΔT is the time between samples, and
τ is the chosen averaging time interval in minutes (3 minutes in the present case).

FIG. 4A shows in black dots the experimental measurements obtained of the remaining energy vs the battery voltage U. The graph represents the discharge curve obtained when a near constant power consumption is applied to the battery. If the power consumption is very low, as is in the case of FIG. 4A, the graph is like the one obtained for a close-to-open circuitry. The low power consumption also entails insignificant voltage drop due to the battery's internal resistance. An example of a function f1 may fit the graph.

However, when the battery operated device is used for a phone call for instance, more power is consumed. In such case, the battery's internal resistance causes higher voltage drops. This is shown in FIG. 4B where the voltage has shifted towards lower values during high current consumption of the battery operated device.

FIG. 4B illustrates a battery discharged by higher battery currents Ibat or higher power consumption. The battery is discharged with various loads of battery current That or power consumption. Once again the measurements (black dots) of the remaining energy vs the battery voltage U are shown on a graph when non constant current or non constant power discharges abruptly occur in the battery operated device. When comparing this graph with the graph of FIG. 4A (for small and constant current load), it is noticeable that the voltage jumps to various places towards smaller values, then returning back to a lower power position on the graph. One example is highlighted with solid and thick line, which corresponds to a longer period of high-power consumption of the battery such as a phone call. After this long period of high-power consumption, the voltage returns to a position of an open-circuit or lower current consumption. These voltage jumps result from the voltage drops caused by the battery's internal resistance. By studying the behavior of the battery to which different power loads of different magnitudes are applied as shown in FIGS. 4A and 4B, it is possible to determine the parameter Alpha and to correct the measured voltage Vbat with the formula U=Vbat+(Power/Alpha).

FIG. 5A illustrates an example of function f1 that provides energy E as a function of corrected battery voltage U. Like in FIG. 4A, the mathematical function f1 may be used to estimate energy E as function of the voltage. The black dots in FIG. 5A confirm how the function f1 obtained from FIG. 4A perfectly fit with the additional measurements. This is just an example of an implementation where a type of battery with the characteristics of ˜950 mAh for Nokia models N95 and N96 and another type of battery with the characteristics of ˜1500 mAh for Nokia models E71 and E72 are used.

In this example, the corrected battery voltage U is divided into several ranges of values, more specifically four ranges of values and the fitted function f1 is mathematically defined accordingly:
If U is above approximately 4.12 Volts in step 510, then the battery is fully charged and the energy E receives the value of 11990.3 Joules in this particular implementation in step 512, it may have a different value:
E=11990.3 Joules; for U>4.12 V
If the voltage U is between approximately 3.58 Volts and 4.12 Volts in step 514, a polynomial is used in step 516 whose eleven coefficients aₙ are given as an example and which are also reported on FIG. 5:
E=Σₙ₌₀¹⁰ αₙU¹⁰⁻ⁿ Joules; for 3.58 Volts≦U≦4.12 Volts;
{a}=[280441848.633443; 8638034427.789333; −111822453888.25409; 755585840151.46533; −2421551614883.2134; −1248889893642.8914; 44207385600533.633; −186277619329495.87; 398182478592934; −451755700378283.81; 216852360852446.53];
If the voltage is between approximately 3.2 Volts and 3.58 Volts in step 518, then another fit function is used in step 520:

$$E = 650 * {( \frac{U - 3.2}{0.45} )}^{2} Joules ;$$

### for 3.2 Volts≦U≦3.58 Volts; and

Finally, if the voltage U is below approximately 3.2 Volts in step 522, then it is assumed that the battery operated device may no longer operate and the remaining energy is 0
Joule in step 524:
E=0 Joule; for U<3.2 Volts.

It will be within the scope of the present invention that in another implementation of the battery operated device with either a single battery or single type of battery, there may be more than five ranges of values of corrected battery voltage U. The accuracy of the measurements and the preciseness desired by the users will determine the number of ranges of values. Another factor will also be the type of the battery.

Moreover, in a different implementation of the battery operated device with either a single battery or single type of battery, there may be less than three ranges of values of corrected battery voltage U.

Furthermore, in an implementation where there are more than one battery or more than one type of batteries, there may be several functions f1, f2, f3 etc. that provide energy values E1, E2, E2 etc. as functions of respectively corrected battery voltage values U1, U2, U3 etc. And each function f1, f2, f3 etc. may operate independently with different ranges of the corrected battery voltage values U1, U2, U3 etc.

Embodiments of the present invention may be implemented in software, hardware, application logic or a combination of software, hardware and application logic. The software, application logic and/or hardware may reside in the battery operated device 1. If desired, part of the software, application logic and/or hardware may reside in the communication network service, part of the software, application logic and/or hardware may reside in battery operated device 1. More specifically, part of the software, application logic and/or hardware may reside in EM circuitry 3 and/or processor 4. In an example embodiment, the application logic, software or an instruction set is maintained on any one of various conventional computer-readable media. In the context of this document, a “computer-readable medium” may be any media or means that may contain, store, communicate, propagate or transport the instructions for use by or in connection with an instruction execution system, apparatus, or device, such as a computer, with one example of a computer described and depicted in FIG. 1. A computer-readable medium may comprise a computer-readable storage medium that may be any media or means that may contain or store the instructions for use by or in connection with an instruction execution system, apparatus, or device, such as a computer.

If desired, the different functions discussed herein may be performed in a different order and/or concurrently with each other. Furthermore, if desired, one or more of the above-described functions may be optional or may be combined. Although various aspects of the invention are set out in the independent claims, other aspects of the invention comprise other combinations of features from the described embodiments and/or the dependent claims with the features of the independent claims, and not solely the combinations explicitly set out in the claims.

It is also noted herein that while the above describes example embodiments of the invention, these descriptions should not be viewed in a limiting sense. Rather, there are several variations and modifications which may be made without departing from the scope of the present invention as defined in the appended claims.

What is claimed is:

1. A method comprising:
measuring a momentary voltage of a battery having one or more specific parameters;
measuring a momentary current of the battery;
providing a corrected voltage based on the measured momentary voltage and the momentary current and the one or more specific parameters; and
providing an amount of available energy E in the battery based on a function f1 of the corrected voltage and the one or more specific parameters.

2. The method of claim 1 wherein the corrected voltage U is defined by:
U=Vbat+(Vbat×Ibat)/Alpha;
where Vbat is the measured momentary voltage;
Ibat is the measured momentary current; and
Alpha is one of the specific parameters.

3. The method of claim 2 wherein Alpha is either a constant or polynomial function.

4. The method of claim 1 wherein the function f1 is determined by measuring a set of voltage drops' of a reference battery having same or similar specific parameters, the set of voltage drops resulting from :
constant and low power consumptions of the reference battery, in idle state; and
higher power consumptions of the reference battery in active state.

5. The method of claim 4 further comprising:
scaling the amount of available energy E in the battery based on a nominal capacity B_size of the reference battery with a scaling factor to provide a scaled amount of available energy E_est.

6. The method of claim 5 further comprising:
averaging the scaled amount of energy available in the battery over time in order to provide a more accurate value by using an exponentially moving average function.

7. The method of claim 4 wherein the function f1 is a mathematical function which varies on four ranges of values:
if the corrected voltage U is above approximately 4.12 Volts, then the battery is fully charged and the amount of available energy E is a maximum value;
if the corrected voltage U is between approximately 3.58 Volts and 4.12 Volts, the amount of available energy E is a first polynomial function of the corrected voltage U;
if the corrected voltage is between approximately 3.2 Volts and 3.58 Volts, then the amount of available energy E is second polynomial function of the corrected voltage U; and
if corrected value is below approximately 3.2 Volts, then the amount of available energy E is 0 Joule.

8. The method of claim 4 wherein the function f1 is a mathematical function which varies on more than 4 ranges of values depending on the one or more specific parameters.

9. The method of claim 1 wherein the powered device has more than one battery with the same or similar specific parameters.

10. The method of claim 9 wherein the batteries have different specific parameters.

11. The method of claim 9 wherein the batteries are connected in series or parallel.

12. The method of claim 1 wherein the function f1 is a look up table showing the relation between the amount of available energy and the corrected voltage.

13. An apparatus comprising:
an energy management circuitry of at least one battery having one or more specific parameters configured:
to measure a momentary voltage and a momentary current of each of the at least one battery;
to provide a corrected voltage U of each of the at least one battery based on the measured momentary voltage, the momentary current and the one or more specific parameters; and
to provide an amount of available energy E in at least one of the at least one battery, each amount of available energy E being based on a function f1 of the corresponding corrected voltage U and the one or more specific parameters.

14. The apparatus of claim 13, wherein the corrected voltage U is defined by:
U=Vbat+(Vbat×Ibat)/Alpha;
where Vbat is the measured momentary voltage;
That is the measured momentary current; and
Alpha is one of the specific parameters.

15. The apparatus of claim 13 wherein each function f1 is determined by measuring a set of voltage drops of a reference battery having same or similar specific parameters as the at least one battery, the set of voltage drops resulting from:
constant and low power consumptions of the corresponding reference battery, in idle state; and
higher power consumptions of the corresponding reference battery, in active state.

16. The apparatus of claim 13 wherein the energy management circuitry further comprises at least a processor configured to perform mathematical functions to compute the amount of available energy E in each of the at least one battery.

17. The apparatus of claim 15 wherein the energy management circuitry is further configured:
to scale the amount of available energy E in the at least one battery according to a nominal capacity B_size of the corresponding reference battery with a scaling factor to provide a scaled amount of available energy E_est of the at least one battery; and
to average the scaled amount of energy available in the at least one battery over time in order to provide a more accurate value by using an exponentially moving average function.

18. A method comprising:
applying a set of low and constant power consumptions to a battery;
measuring a first set of voltage drops of the battery respectively resulting from the set of low and constant power consumptions;
applying a set of high power consumption to the battery;
measuring a second set of voltage drops of the battery respectively resulting from the set of high power consumptions; and
determining a parameter alpha specific to the battery by correlating the power consumption applied to the battery with the resulting voltage drops.

19. The method of claim 18 wherein the parameter alpha is either a constant or polynomial function.

20. A computer-readable medium encoded with instruction that, when executed by a computer, perform:
measuring a momentary voltage of a battery having one or more specific parameters;
measuring a momentary current of the battery;
providing a corrected voltage based on the measured momentary voltage and the momentary current and the one or more specific parameters; and
providing an amount of available energy E in the battery based on a function f1 of the corrected voltage and the one or more specific parameters.
